(19) United States
(12) Patent Application Publication
(10) Pub. No.: US 2003/0073419 A1
(43) Pub. Date: Apr. 17, 2003

(54) Power control in polar loop transmitters

(75) Inventor: Peter Edward Chadwick, Swindon (GB)

Correspondence Address: JAMES M. BAGARAZZI, Dority & Manning, Attorneys at Law, P.A., P.O. Box 1449, Greenville, SC, 29602, US

(73) Assignee: Zarlink Semiconductor Limited

(21) Appl. No.: 10/267,904

(22) Filed: Oct. 9, 2002

(30) Foreign Application Priority Data
Oct. 10, 2001 (GB) 0124331.0

(51) Int. Cl. H04B 1/04; H04B 17/00; H03C 1/62; H01Q 11/12

(52) U.S. Cl. 455/126; 455/115

(57) ABSTRACT

A polar loop transmitter circuit arrangement comprises a circuit input, a circuit output, a controllable signal source, a modulator connected between the signal source and the circuit output, a first signal-amplitude-sensitive element having its input connected to the circuit input, a second signal-amplitude-sensitive element having its input connected to the circuit output, a comparator, and at least one controllable attenuator. An output of each of the signal-amplitude-sensitive elements is connected to a respective input of the comparator, and an output of the comparator is connected to a control input of the modulator. Another controllable attenuator may also be connected between the circuit output and an input of the second signal-amplitude-sensitive element. The signal-amplitude-sensitive elements may correspond to amplitude detectors in some embodiments of the technology, and to logarithmic amplifiers in other embodiments. Additional features for comparing the respective phases of the circuit input and the circuit output may be utilized to control the signal source.

### CROSS-REFERENCE TO RELATED APPLICATIONS

The present application claims priority to currently pending United Kingdom Patent Application number 0124331.0, filed on Oct. 10, 2001.

### STATEMENT REGARDING FEDERALLY SPONSORED RESEARCH OR DEVELOPMENT

N/A

### BACKGROUND OF THE INVENTION

The polar loop transmitter was first described by Gosling and Petrovic in Electronics Letters, 1979, 15 (10) pp 286-288. This was a development of the work of Kahn “Single Sideband Transmission by Envelope Elimination and Restoration,” Proc. IRE 1952, 40, pp 803-806. The basic scheme of the polar loop transmitter is shown in FIG. 1.

Referring to FIG. 1, the transmitter 100 generally comprises an RF input 101 to which is applied in use an input signal, and a voltage controlled oscillator (VCO) 102. A signal output of the VCO 102 is fed via a controllable gain amplifier 104 to an RF output 103, to provide a modulated RF output signal. The RF input 101 is connected both to a first amplitude detector 105 and to a first limiting amplifier 106. Similarly, the RF output 103 is connected both to a second amplitude detector 107 and to a second limiting amplifier 108. This arrangement, therefore, separates both input signals and output signals into amplitude and phase components.

The outputs of the limiting amplifiers 106, 108 are connected to respective inputs of a phase comparator 109, which generates a signal on its output which is proportional to the difference in phase between the respective signals at circuit input 101 and circuit output 103. The output of the phase comparator 109 is connected to a control input of the VCO 102, via a low-pass filter 110, to control the phase of the signal generated by the VCO in order to minimize the phase difference. This arrangement thus constitutes a phase locked loop.

Instead of being coupled to the output of the amplifier 104, the input of the limiting amplifier 108 may be coupled directly to the output of the VCO 102. This variant is not so beneficial since there is no compensation of amplitude to phase variations introduced in the amplifier 104. Outputs of the amplitude detectors 105 and 107 are connected to respective inputs of a comparator 111, which provides a signal on its output dependent on the difference in the instantaneous amplitudes of the respective signals at circuit input 101 and circuit output 103. The output of the comparator 111 is connected to a gain control input of the controllable amplifier 104, via a second low-pass filter 112. The controllable gain amplifier 104 is, therefore, caused to modulate the output of the VCO 102 so that its amplitude follows variations in the amplitude of the input signal. Variations in the power of the input signal cause sympathetic variations in the output power.

### OBJECTS AND SUMMARY OF THE INVENTION

Objects and advantages of the invention will be set forth in part in the following description, or may be obvious from the description, or may be learned through practice of the invention.

The present technology offers many advantages for polar loop transmitter circuits. More particularly, aspects of the exemplary polar loop transmitter arrangements provided herein provide compensation of amplitude to phase variations introduced in the amplifier components of such circuits. When utilizing logarithmic amplifiers in accordance with the present subject matter, additional advantages may be present since the phase of a logarithmic amplifier output signal does not vary with the amplitude of the input signal.

These and other objects and advantages of the presently disclosed technology may be achieved by improved polar loop transmitter circuits, several exemplary embodiments of which are presented herein. In one exemplary embodiment, a polar loop transmitter circuit arrangement includes a circuit input, a circuit output, a controllable signal source, a modulator, first and second signal-amplitude-sensitive elements, a comparator, and at least one controllable attenuator. The modulator is preferably connected between the signal source and the circuit output. An input of the first signal-amplitude-sensitive element is connected to the circuit input, while an input of the second signal-amplitude-sensitive element is connected to the circuit output. The comparator preferably receives the output of each of the signal-amplitude-sensitive elements and provides its output to a control input of the modulator. The controllable attenuator is preferably connected between the circuit output and the input to the second signal-amplitude sensitive element. In some embodiments, a second controllable attenuator may be provided between the modulator and the circuit output. The signal-amplitude-sensitive elements of such first exemplary polar loop transmitter circuit may correspond to amplitude detectors or to logarithmic amplifiers.

Another exemplary embodiment of the present technology corresponds to a polar loop transmitter circuit arrangement including a circuit input, a circuit output, a controllable signal source, a modulator, a first logarithmic amplifier, a second logarithmic amplifier, a comparator, and a controllable attenuator. The modulator is preferably connected between the signal source and the circuit output. An input of the first logarithmic amplifier is connected to the circuit input, while an input of the second logarithmic amplifier is connected to the circuit output. The comparator preferably receives an output of each of the logarithmic amplifiers and provides its output to a control input of the modulator. The controllable attenuator is preferably connected between the circuit output and the input to the second logarithmic amplifier. The logarithmic amplifiers of such embodiment may correspond to successive detection logarithmic amplifiers. In some embodiments, a second controllable attenuator may be provided between the modulator and the circuit output.

In accordance with more particular aspects of the present technology, selected of the aforementioned exemplary embodiments may also include a mixer connected between the circuit output and the second signal-amplitude-sensitive element (or logarithmic amplifier). Such mixer may be an image-reject mixer in some embodiments of the present technology. Additional embodiments may include a power control device connected to a third input of the comparator to effect shaping of rising and falling power levels in the circuit output signal, thus reducing signal splatter or “key clicks” in time division multiple access (TDMA)-type signal transmissions. Other embodiments may further include signal-phase-sensitive elements for respectively receiving the circuit input and the circuit output and providing outputs to a phase comparator, which may then be connected to a control input of the signal source.

Additional objects and advantages of the invention will be set forth in part in the description that follows, and in part will be obvious from the description, or may be learned by practice of the invention. The objects and advantages of the invention may be realized and attained by means of the instrumentalities and combinations particularly pointed out in the appended claims.

The accompanying drawings, which are incorporated in and constitute a part of this specification, illustrate at least one presently preferred embodiment of the invention as well as some alternative embodiments. These drawings, together with the description, serve to explain the principles of the invention but by no means are intended to be exhaustive of all of the possible manifestations of the invention.

### BRIEF DESCRIPTION OF THE DRAWINGS

A full and enabling description of the present subject matter, including the best mode thereof, directed to one of ordinary skill in the art, is set forth in the specification, which makes reference to the appended figures, in which:

FIG. 1 is a schematic diagram of a prior art polar loop transmitter circuit arrangement; and

FIG. 2 is a schematic diagram of a first exemplary polar loop transmitter circuit arrangement in accordance with the presently disclosed technology; and

FIG. 3 is a schematic diagram of a second exemplary polar loop transmitter circuit arrangement in accordance with the presently disclosed technology.

Repeat use of reference characters throughout the present specification and appended drawings is intended to represent same or analogous features or elements of the presently disclosed technology.

### DETAILED DESCRIPTION OF THE PREFERRED EMBODIMENTS

Reference now will be made in detail to the presently preferred embodiments of the invention, one or more examples of which are illustrated in the accompanying drawings. Each example is provided by way of explanation of the invention, which is not restricted to the specifics of the examples. In fact, it will be apparent to those skilled in the art that various modifications and variations can be made in the present invention without departing from the scope or spirit of the invention. For instance, features illustrated or described as part of one embodiment, can be used on another embodiment to yield a still further embodiment. Thus, it is intended that the present invention cover such modifications and variations as come within the scope of the appended claims and their equivalents.

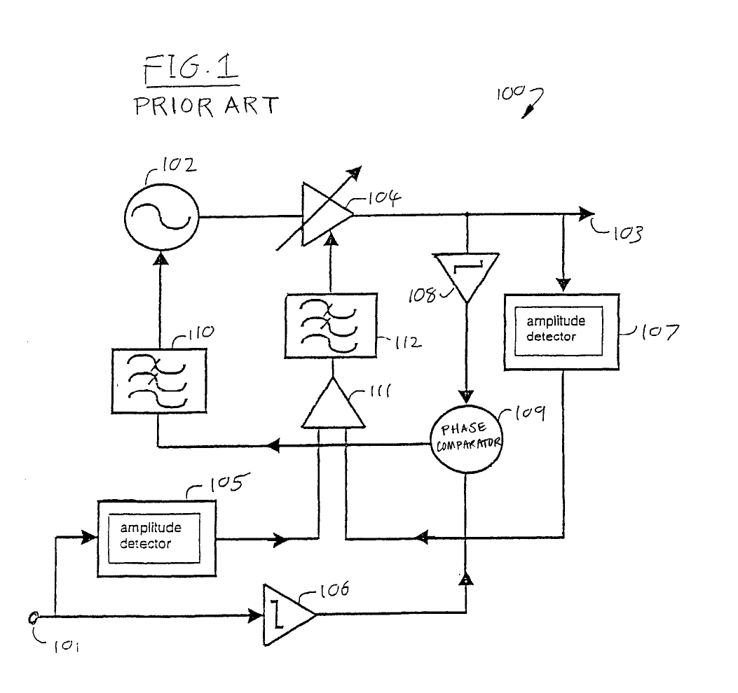

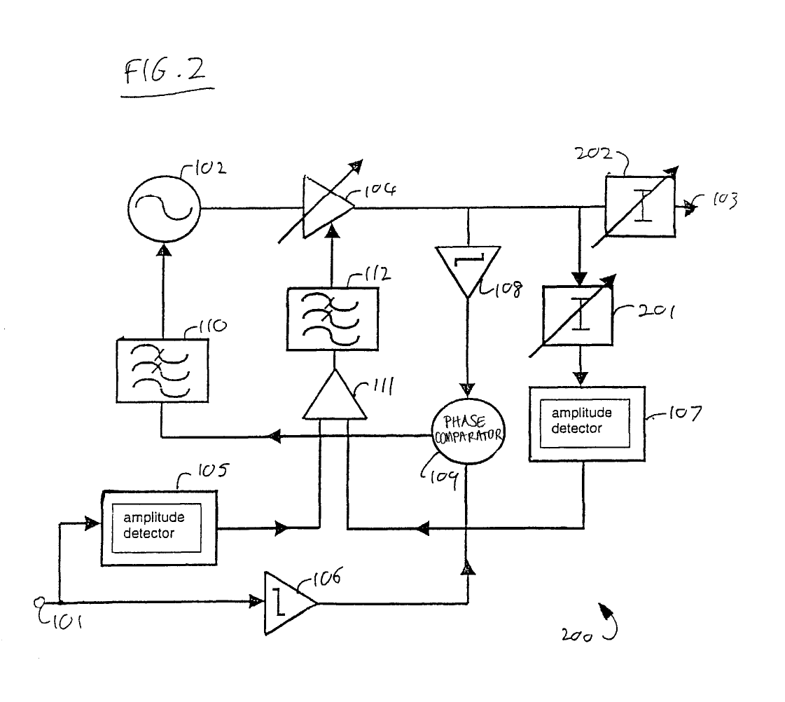

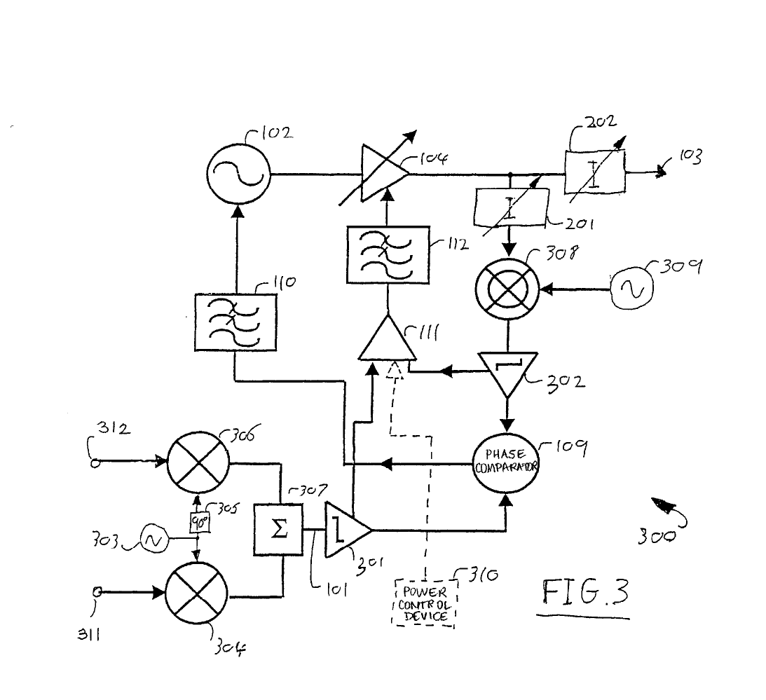

In FIGS. 2 and 3, certain reference numerals are the same as those used in FIG. 1 for like elements.

Referring to FIG. 2, a polar loop transmitter circuit arrangement 200 in accordance with the invention further includes a first controllable attenuator 201, which is connected between the output of the modulator 104 and the input of the amplitude detector 107. The arrangement 200 also includes a second controllable attenuator 202, which is connected between the output of the modulator 104 and the circuit output 103.

The attenuators 201, 202 may be continuously variable attenuators, or they may be step attenuators which are controllable in a step-wise fashion. The amplitude detectors 105 and 107 preferably operate at substantially identical input powers, thereby minimizing potential distortion caused by them.

To increase the output power, a controller (not shown) controls the first attenuator 201 to increase its attenuation. This results in a smaller signal at the input of the amplitude detector 107 for a short period, during which the feedback loop constituted by the comparator 111 and the modulator 104 effects an increase in the power at the circuit output 103 to the point where the amplitude of the signal received at the amplitude detector 107 is restored to its previous value. Since the input power is the same for each amplitude detector 105, 107, distortion is minimized.

The maximum attenuation which can be provided by the first attenuator 201, which dictates the maximum power at the circuit output 103, is determined during the design process. The maximum attenuation is determined having regard to the noise figures at the amplitude detectors 105, 107 and the comparator 111, and to the permissible level of noise sidebands, in terms of channel noise as well as Out of Band and Spurious Emissions (as defined in ITU-R Recommendations SM 328-10 and SM 329-7).

To decrease the output power, the controller (not shown) controls the first attenuator 201 to decrease its attenuation. This results in a larger signal reaching the input of the amplitude detector 107 for a short period, until the comparator 111 and the modulator 104 effect a decrease in the output power to restore the signal level at the input of the amplitude detector to its previous value.

The minimum output power level is achieved when the attenuation provided by the first attenuator 201 reaches its minimum possible value, which typically is zero. If a further reduction in output power is required, the second attenuator 202 is controlled to increase its attenuation from its minimum value. The attenuation of the second attenuator 202 is preferably increased above its minimum value only if the first attenuator 201 is controlled to adopt its minimum attenuation and a further reduction in output power is still required. This helps to ensure that power consumption is kept as low as possible.

Under certain operating conditions, power consumption is reduced by controlling the controllable gain amplifier 104 to reduce its DC power consumption. Significant power consumption reductions can be made, especially when low output power is required, while maintaining adequate linearity characteristics even when non-constant envelope modulations are used. Preferably, an algorithm is implemented to obtain the required levels of output power with acceptable noise performance and minimum power consumption by suitable control of the amplifier 104 and the attenuators 201, 202. It should be appreciated that development of a particular such algorithm is within the purview of one of ordinary skill in the art and thus additional details regarding such algorithms are not presented herein.

Referring now to FIG. 3, an alternative power loop transmitter circuit 300 is shown. The arrangement 300 has, in place of the amplitude detectors 105, 107 and limiting amplifiers 106, 108 of the arrangement of FIG. 2, first and second logarithmic amplifiers 301 and 302. Each of the logarithmic amplifiers 301, 302 preferably has two outputs, one output providing a signal containing information about the phase of the signal received at its input, and the other output providing a signal having an amplitude proportional to the logarithm of the amplitude of the signal received at its input. The outputs of the logarithmic amplifiers 301, 302 which provide signals containing phase information are connected to respective ones of the inputs of the phase comparator 109. The outputs of the logarithmic amplifiers 301, 302 which provide signals representative of the logarithm of the amplitude of the respective input signals are connected to respective ones of the inputs of the comparator 111.

The logarithmic amplifiers 301 and 302 may be successive detection logarithmic amplifiers. Such amplifiers have an RF output which is amplitude limited and can be designed to have a constant phase limited output, i.e., the phase of the output signal does not vary with the amplitude of the input signal. Successive detection amplifiers are commonly used in radio receivers for cellular telephony, where the amplitude output is referred to as the Received Signal Strength Indicator (RSSI) output. In radar applications, the amplitude output of a successive detection amplifier is known as the video output. Alternatively, the logarithmic amplifiers 301, 302 may be true logarithmic amplifiers such as that described by Barber and Brown in IEEE Journal of Solid States Circuits, June 1980—“A True Logarithmic Amplifier for Radar I.F. Applications,” followed by a respective amplitude detector. A true logarithmic amplifier may include a limiting amplifier and a linear amplifier connected in parallel. In general terms, the amplifiers 301, 302 are such that each provides an output signal which is at least approximately logarithmically related to its input signal. A polar loop transmitter having logarithmic amplifiers is the subject of U.S. patent application Ser. No. 10/114,429, which is hereby incorporated by reference for all purposes. The above-mentioned references are hereby incorporated into the present application for all purposes.

An advantage achieved using the logarithmic amplifiers 301, 302 in the polar loop transmitter 300 is that, for any given difference in amplitude (in dB, i.e., having a given ratio therebetween) between the circuit input 101 and the circuit output 103, the difference voltage representing an error in amplitude is constant within the errors of the respective logarithmic amplifiers. Accordingly, the degrees of error between the correct (ideal) amplitude and the actual amplitude of the modulated input signal provided at the output 103 is not dependent on the amplitude of the signal received at the input 101. Distortion of low input signal levels is thereby reduced. The art of producing matched logarithmic strips for use in logarithmic amplifiers is well known, having been practiced for many years in the field of monopulse radar.

The polar loop transmitter 300 may further comprise in-phase and quadrature modulation inputs 311 and 312. Signals received at the inputs 311, 312 are mixed with, respectively, a signal provided by a local oscillator 303 in a first balanced modulator 304, and a version of the local oscillator signal, shifted by a 90° phase shifter 305, in a second balanced modulator 306. In-phase and quadrature local oscillator signals may be provided instead through the use of a different phase shift network, such as one including a +45° phase shifter and a −45° phase shifter. Outputs of the balanced modulators 304 and 306 are provided to a combiner 307, which combines the signals received at its inputs and provides the result via the input 101 to the first logarithmic amplifier 301.

A mixer 308 is connected between the RF output 103 of the transmitter and the input of the second logarithmic amplifier 302. The mixer 308 receives a signal provided by a frequency-determining source 309, which may be a frequency synthesizer. The frequency of operation of the frequency-determining source is selected such that signals at the output of the mixer 308 are of the same nominal frequency as signals at the input 101. This allows the output frequency to differ from the input frequency, and also reduces the negative effects of spurious signals, including signal intermodulation products.

In one embodiment, the mixer 308 is a conventional mixer and filtering is provided to remove or to reduce the image frequency signals generated by the mixer. This filtering may be provided by frequency roll-off in the mixer 308, by frequency roll-off in the logarithmic amplifier 202, or by a discrete filter (not shown) connected between the mixer 308 and the logarithmic amplifier 202. In a more particular embodiment, the mixer 308 is an image-reject mixer, as represented in FIG. 3.

The polar loop transmitter 300 as described above may be modified by providing comparator 111 with a third input, and by the connection of an output of a power control device 310 to this third input. This is shown in dotted lines in FIG. 3. The amplitude of a signal provided to the comparator 111 by the power control device 310 helps to determine the power of signals provided at the output 103. This constitutes a particularly convenient scheme for effecting power control. When the polar loop transmitter 300 is used in a time division multiple access (TDMA) or similar system, the power control device 310 effects shaping (i.e., rounding) of the rise and fall of the power of the signal provided at the output 103 to reduce the effects of “splatter” or “key clicks,” which are produced by sharp edged radio frequency (RF) envelopes. The power control device 310 effects fine power control, which is particularly useful where one or both of the attenuators 201, 202 are stepped attenuators.

A polar loop transmitter in accordance with this invention has potential applications in many fields, including cellular radio. Where transmitters of minimum power consumption are required, and complexity and cost constraints are such that minimum geometry semiconductor fabrication techniques are desirable, certain difficulties arise even when small amounts of RF power are required. Difficulties can arise when only low voltage supplies are allowable, since this can require the use of low impedances. Similarly, because of these constraints, it is desirable to minimize the number of external filters, but system requirements can place significant constraints on the wideband noise that can be produced. In turn, this leads to a requirement to maximize signal voltages, which can be incompatible with the allowable supply voltage of the semiconductor fabrication technique. An exemplary polar loop transmitter in accordance with the present invention allows for a large proportion of the circuitry to be implemented in minimum geometry low supply voltage techniques. Additionally, the output amplifier 104, although shown as a modulated amplifier, could be a modulating stage followed by an amplifier. Such an amplifier could be a high efficiency amplifier operating in Class E, with the distortion products resulting from the use of non-constant envelope signals reduced by means of the amplitude feedback inherent in the system.

This invention can be implemented optically by substituting the oscillator 102 with a frequency modulated light source, such as a laser, and by substituting the controllable gain amplifier 104 and the attenuators 201 and 202 with devices whose light transmissibility is proportional to an applied voltage, such as Kerr cells. In this case, the image reject mixer 308 would be replaced with a photodetector fed by an additional laser element.

The logarithmic amplifiers 301, 302 preferably provide a power range equal to the dynamic range of the logarithmic amplifiers minus the peak-to-average ratio of the output signal. The first attenuator 201 provides a greater power range than would be possible for a given dynamic range of the logarithmic amplifiers.

While at least one presently preferred embodiment of the invention has been described using specific terms, such description is for illustrative purposes only, and it is to be understood that changes and variations may be made without departing from the spirit or scope of the following claims.

What is claimed is:

1. A polar loop transmitter circuit arrangement comprising:
a circuit input;
a circuit output;
a controllable signal source;
a modulator connected between said signal source and said circuit output;
a first signal-amplitude-sensitive element having an input connected to said circuit input;
a second signal-amplitude-sensitive element having an input connected to said circuit output;
a comparator, wherein an output of each of said signal-amplitude-sensitive elements is connected to a respective input of said comparator, and wherein an output of said comparator is connected to a control input of said modulator; and
a controllable attenuator connected between said circuit output and an input of said second signal-amplitude-sensitive element.

2. A polar loop transmitter circuit arrangement as in claim 1, further comprising a second controllable attenuator connected between said modulator and said circuit output.

3. A polar loop transmitter circuit as in claim 2, further comprising:
a first limiting amplifier having an input connected to said circuit input;
a second limiting amplifier having an input connected to said circuit output; and
a phase comparator, wherein an output of each of said limiting amplifiers is connected to a respective input of said phase comparator, and wherein an output of said phase comparator is connected to a control input of said signal source.

4. A polar loop transmitter as in claim 3, further comprising:
a first low-pass filter connected between said comparator output and the control input of said modulator; and
a second low-pass filter connected between said phase comparator output and the control input of said signal source.

5. A polar loop transmitter circuit arrangement as in claim 1, wherein said first and second signal-amplitude-sensitive elements are amplitude detectors.

6. A polar loop transmitter circuit arrangement as in claim 5, further comprising:
a first limiting amplifier having an input connected to said circuit input;
a second limiting amplifier having an input connected to said circuit output; and
a phase comparator, wherein an output of each of said limiting amplifiers is connected to a respective input of said phase comparator, and wherein an output of said phase comparator is connected to a control input of said signal source.

7. A polar loop transmitter circuit arrangement as in claim 6, further comprising:
a first low-pass filter connected between said comparator output and the control input of said modulator; and
a second low-pass filter connected between said phase comparator output and the control input of said signal source.

8. A polar loop transmitter circuit arrangement as in claim 1, wherein said first and second signal-amplitude-sensitive elements are logarithmic amplifiers.

9. A polar loop transmitter circuit arrangement as in claim 1, further comprising a mixer connected between said circuit output and the input of said second signal-amplitude-sensitive element.

10. A polar loop transmitter circuit arrangement as in claim 9, in which said mixer is an image-reject mixer.

11. A polar loop transmitter circuit arrangement as in claim 1, further comprising a power control device connected to a third input of said comparator, wherein said power control device effects shaping of rising and falling power levels of the signal at said circuit output to reduce the effects of signal splatter.

12. A polar loop transmitter circuit arrangement comprising:
a circuit input;
a circuit output;
a controllable signal source;
a modulator connected between said signal source and said circuit output;
a first logarithmic amplifier having an input connected to said circuit input and providing at least one output signal therefrom;
a second logarithmic amplifier having an input connected to said circuit output and providing at least one output signal therefrom;
a comparator, wherein an output of each of said logarithmic amplifiers is connected to a respective input of said comparator, and wherein an output of said comparator is connected to a control input of said modulator; and
a controllable attenuator connected between said circuit output and an input of said second logarithmic amplifier.

13. A polar loop transmitter circuit arrangement as in claim 12, further comprising a second controllable attenuator connected between said modulator and said circuit output.

14. A polar loop transmitter circuit arrangement as in claim 12, further comprising a mixer connected between said circuit output and the input of said second logarithmic amplifier.

15. A polar loop transmitter circuit arrangement as in claim 14, in which said mixer is an image-reject mixer.

16. A polar loop transmitter circuit arrangement as in claim 12, further comprising a power control device connected to a third input of said comparator, wherein said power control device effects shaping of rising and falling power levels of the signal at said circuit output to reduce the effects of signal splatter.

17. A polar loop transmitter circuit arrangement as in claim 12, further comprising:
a phase comparator having respective inputs connected to an output of said first logarithmic amplifier and an output of said second logarithmic amplifier, wherein said phase comparator provides an output connected to a control input of said signal source.

18. A polar loop transmitter circuit arrangement as in claim 17, further comprising:
a first low-pass filter connected between said comparator output and the control input of said modulator; and
a second low-pass filter connected between said phase comparator output and the control input of said signal source.

19. A polar loop transmitter circuit arrangement as in claim 12, wherein said circuit input comprises first and second input nodes for receiving respective inphase and quadrature components of an input signal.

20. A polar loop transmitter circuit arrangement as in claim 12, wherein said logarithmic amplifiers are successive detection logarithmic amplifiers.
